(19) United States
(12) Patent Application Publication
(10) Pub. No.: US 2009/0174400 A1
(43) Pub. Date: Jul. 9, 2009

(54) Arrangement for Non-Contact Defined Movement of at Least One Magnetic Body

(76) Inventors: Wilfried Andra, Jena (DE); Holger Lausch, Jena (DE); Michael Brand, Grossrückerswalde (DE); Christoph Werner, Jena (DE)

Correspondence Address: JORDAN AND HAMBURG LLP, 122 EAST 42ND STREET, SUITE 4000, NEW YORK, NY, 10168, US

(21) Appl. No.: 12/227,272

(22) PCT Filed: May 16, 2007
(86) PCT No.: PCT/DE2007/000910

§ 371 Date: Dec. 5, 2008

(30) Foreign Application Priority Data
May 16, 2006 (DE) 10 2006 023 428.6
Jun. 20, 2006 (DE) 10 2006 028 704.5

(51) Int. Cl. G01R 33/038

(52) U.S. Cl. 324/244; 324/260; 324/261

(57) ABSTRACT

The invention relates to an arrangement for the non-contact defined movement of at least one magnetic body, free to move in at least one dimension. A simple arrangement of this type, taking up a reduced volume, of universal application, for both positioning and orientation and also for energy generation and transmission, can be achieved, by means of arranging the body with a magnetic moment in the primary magnetic field of at least one permanent magnet which moves in a defined manner, said body having a secondary magnetic field extending from the body, aligned with the primary magnetic field. At least one magnetic field sensor is provided to record the secondary magnetic field in any position of the body.

### BACKGROUND OF THE INVENTION

The invention relates to an arrangement for non-contact defined movement of at least one magnetic body It can be used in all technical and medical applications that focus on the determination of the path, position and orientation of magnetic bodies in inaccessible channels and at inaccessible locations.

### SUMMARY OF THE INVENTION

The task of this invention is to create an arrangement for the non-contact defined movement of a test object that is universally applicable for positioning and orientating the test object (the magnetic body) and also for determining its position in space. Furthermore, the arrangement shall be practicable for energy generation and transmission and for the determination of specific physical and/or chemical properties of the test object and its immediate surroundings. Finally, the arrangement shall allow to use very small and compact structures for special applications.

### BRIEF SUMMARY OF THE INVENTION

According to the present invention, this task is solved by providing an apparatus for effecting non-contact defined movement of at least one magnetic body, the apparatus including a body having a magnetic moment, at least one permanent magnet and at least one magnetic field sensor, wherein the body is arranged free to move in at least one dimension in a primary magnetic field of the at least one permanent magnet, the permanent magnet has a secondary magnetic field extending from the body and aligned with the primary magnetic field and the at least one magnetic field sensor registers the secondary magnetic field in any position of the body. In other words: If the primary magnetic stray field (primary magnetic field) that extends from the permanent magnet moves relative to the magnetic body (test object), changes of the alignment of the secondary magnetic stray field (secondary magnetic field) will be caused and their strength, direction and phase angle relative to the primary stray field are measured on one level or in space by using a magnetic field sensor. As the test object or the test objects is/are movably supported in capsules they can be specifically aligned or moved in another way by means of the moving permanent magnet (field donor). The permanent magnet itself can have a rotation-symmetrical design and is radially magnetized, i.e. for example different polarities are at the ends of a cylinder diameter. The motion of the permanent magnet can be initiated by a motor that turns the rotation body around its axis of symmetry. Advantageously, the test object is designed as a rod-shaped or even better as a spherical dipole that can freely move in three dimensions in the supporting fluid within the capsule. The phase angle between the primary magnetic field and the secondary one effects a lag of the secondary magnetic field from which the viscosity of the supporting fluid can be inferred. It goes without saying that the free movability of the dipole can also be guaranteed by a gimbal suspension.

The number of the magnetic field sensors or the design of the magnetic field sensor, which is advantageously a magnetometer, depends on the degrees of freedom of the motion of the magnetic body within the capsule. The magnetic field sensor/magnetic field sensors can be arranged or supported in any way in space; they can also change their positions in the course of time and be firmly connected to the permanent magnet or move synchronically with it. But in an advantageous embodiment they are firmly arranged in space.

The secondary magnetic field can be measured by determining the change relative to the primary field at the location of the sensor (reference field). If the permanent magnet and thus the primary magnetic field rotate relative to the magnetic field sensor, the reference field will change in dependence on the angle to the sensor axis. But it is advantageous to compensate the primary magnetic field at the location of the sensor in such a way that its value is constant or preferentially zero. This can be achieved at best by using a permanent-magnetic compensation system consisting of a permanent magnet arrangement that is firmly connected to the rotation-symmetrical permanent magnet and mounted so that it can pivot around the same axis and it generates a field that has the same strength as the primary magnetic field and is directed opposite to it. The compensation of the primary magnetic field can also be achieved by an electromagnetic compensation system that is designed in such a way that at least one electrical coil is arranged coaxially to the rotation axis of the permanent magnet and can be rotated synchronically with it. Also in this case a field is generated that is preferably directed opposite to the primary magnetic field and has the same intensity as the latter.

It is also possible to arrange several inventive arrangements one behind the other so that the respective secondary magnetic field is used as a primary magnetic field that excites other magnetic bodies (test objects). If the inventive arrangement is not only to be used for transmitting motions, for localizing and indicating positions of the magnetic body or a casing assigned to it, but also for orientating said body or for indicating its orientation, the capsule containing the freely movable magnetic body is surrounded by a preferentially three-dimensionally acting coil system that is fixed at the capsule. If the magnetic body is moved in the capsule, not only the position of the secondary field relative to the primary field will be changed but also currents will be induced in the coil system that are transmitted to an evaluation and control unit that uses these values to determine the orientation of the magnetic body in space and possibly indicates it. Vice versa, the coil system can be powered in a suitable manner to achieve a desired spatial orientation of the magnetic body.

The coil system and magnetic bodies can also act as a generator for producing energy. This generator energy is transmitted to one energy storage or at least to one consumer load. For this purpose, the individual coils of the coil system are preferentially connected in series to achieve a maximum efficiency of the generator.

To transmit motions, the generator capsule (capsule containing the magnetic body) is advantageously fixed on the one side within a casing which contains on the other side a transmission capsule. The transmission capsule has a rotation axis that is at least almost aligned with the rotation axis of the magnetic body in the generator capsule.

The evaluation and control unit can also be electrically connected to the coil system in such a way that it powers the coil system so that in the capsule a magnetic field is induced that superimposes the secondary magnetic field of the magnetic body to the defined motion of said body and the capsule.

Further advantageous embodiments and effects of the invention are demonstrated in the following verbal explanations, and in the drawings.

### BRIEF DESCRIPTION OF THE DRAWINGS

In the following, four examples explain the invention in detail in a schematic drawing. They show:

FIG. 1 a front view of a first embodiment of the invention,

FIG. 2 a top view of the first embodiment of the invention,

FIG. 3 a modified capsule as a second embodiment of the invention,

FIG. 4 an axial section of a third embodiment of the invention, and

FIG. 5 an axial section of a fourth embodiment of the invention in which the invention is used both for positioning and orientating and for generating energy and transmitting it.

### DETAILED DESCRIPTION OF THE INVENTION

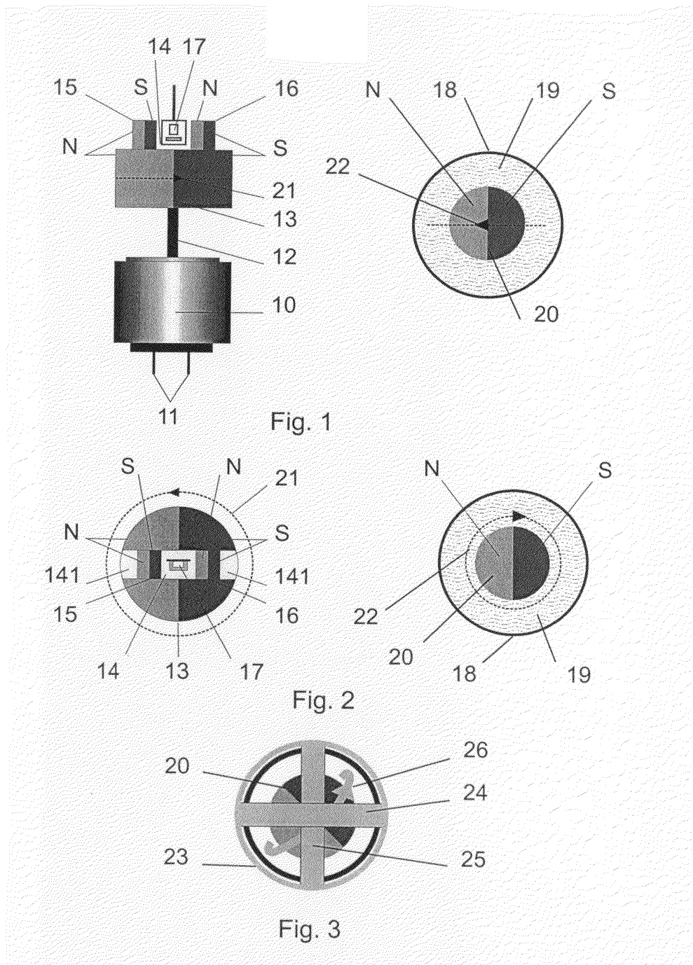

In the FIGS. 1 and 2, a motor 10 that is equipped with electrical terminals 11 sets a rotation-symmetrical permanent magnet (cylindrical field donor) 13 into rotations around a geometric axis X-X (covered) via a shaft 12. The permanent magnet 13 is radially magnetized and is provided with a north pole half N and a south pole half S. At the permanent magnet 13, block-shaped smaller permanent magnets 15, 16 that enclose a gap 14 are fixed by a holder 141 and their poles are also N and S. In the gap 14, a magnetic field sensor 17, which is acting three-dimensionally in this example, is arranged rigidly and separately from the magnets 13, 14, 15. The permanent magnet 13 generates a primary magnetic field that contains a non-magnetic capsule 18 in which a freely swimming magnetic body (spherical dipole) with the poles N and S is supported in a non-magnetic fluid 19 and the magnetic stray field (secondary magnetic field) of said body is to be measured by using the magnetic field sensor 17. If the permanent magnet 13 is rotated towards an arrow 21, the magnetic body 20 will rotate towards an arrow 22, i.e. into the opposite direction. As the permanent magnets 15, 16 build up a magnetic field, which has the same intensity as the primary magnetic field in the space 14 but is oppositely directed, only the secondary magnetic field, which is generated by the magnetic body 20 and aligned with the primary magnetic field, acts on the magnetic field sensor 17.

The embodiment shown in the FIGS. 1 and 2 is used both for transmitting motions to the magnetic body 20 and for localizing the magnetic body 20 by means of the magnetic field sensor 17. The invention is not restricted to the illustrated designs and arrangements of the permanent magnet 13, the compensation system 15, 16, the magnetic field sensor 17 and the magnetic body 20.

Deviating from the FIGS. 1 and 2, FIG. 3 shows a capsule 18 to which a three-dimensionally acting coil system with induction coils 23, 24, 25 is assigned. In the capsule 18, a spherical dipole 20 is supported in a fluid 19 in such a way that it can freely move (indicated by an arrow 26). If the dipole 20 is moved in a manner similar to the one of the FIGS. 1 and 2, it will normally generate different currents in the coils 23, 24, 25 that are transmitted to an evaluation unit not shown and said unit uses the currents to determine the orientation of the dipole 20 or the capsule 18 in space and indicates it.

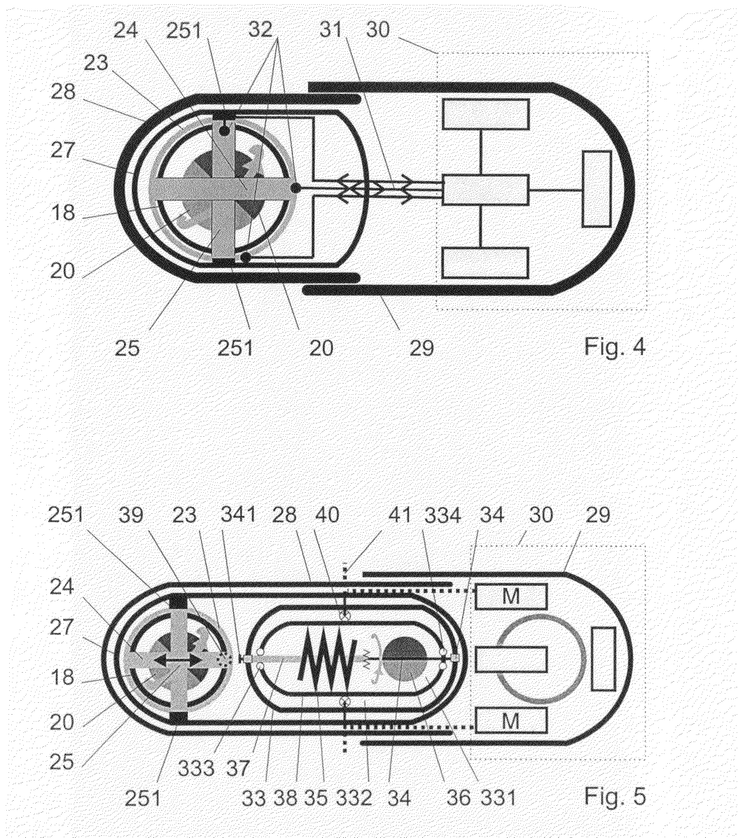

In FIG. 4, a magnetic body 20 is supported in a capsule 18 so that it can freely move in it. Said capsule is surrounded by a coil system 23, 24, 25 the fastenings of which at a casing are marked by 251. The capsule 18 and the coil system 23, 24, 25 are fixed in a casing 27 that is surrounded by an external casing shell 28. A second casing shell 29 contains an evaluation and control unit 30 that has electric connections 31 to contacts 32 of the coil system 23, 24, 25. The two casing shells 28, 29 can be telescoped. The electrical energy generated in the coil system 23, 24, 25 by the motion of the magnetic body 20 is transmitted via the electric connections 31 for driving electromotors with flange-mounted motion tractors (not shown) and thus for remotely controlled motions. The generated electromagnetic energy can also be used to power capsule components, such as sensors, actuators, data transmission and control systems, accumulators, etc. Finally, it is possible to use the capsule 18 with its surrounding coil system 23, 24, 25 exclusively for localizing test objects and determining their position in space. For this purpose, the electric connections 31 are advantageously designed in such a manner that they transfer the signals to be processed from the coils 23, 24, 25 to the evaluation and control unit 30 and send control signals from the evaluation and control unit 30 via contacts 32 to the coils 23, 24, 25 to align the dipole 20. The evaluation and control unit 30 can also be designed as a remotely controlled system.

In FIG. 5 two external casing shells 28, 29 are telescoped. One casing shell 28 contains a protection casing 27 for the capsule 18, which is provided with the coil system 23, 24, 25 and in which the dipole 20 is mounted so that it can pivot, and an oblong transmission capsule 33. A shaft 34 is supported in the center of the longitudinal direction of the transmission capsule 33 and on this shaft a transmission screw and a magnetic dipole 36 are installed. Preferentially, this dipole 36 mounted on the shaft 34 on the side not facing the capsule 18 has a comparably smaller magnetic moment than the dipole 20 in the capsule 18. An induction coil 37 is provided for the dipole 36 on the transmission capsule 36. A partition 38 that is rotation-symmetrically arranged relative to the shaft 34 divides the interior of the fluid-containing transmission capsule 33 radially into one internal subspace 331 and one external subspace 332 that are connected one with the other via control valves 333, 334. The end of the shaft 34 that is facing the capsule 18 is provided with a pressure surface 341 and an inflating bag or a switch 39 is positioned opposite to it. Deviating from the representation shown in FIG. 5 the transmission screw 35 can itself be designed as a magnetic dipole.

The external casing shell 29 contains an evaluation and control unit 30 that comprises sensors, motors, accumulators, data processing and transmitting means and possibly a fluid reservoir.

Drive taps 40 and drive axes 41 are used to transfer the energy if the coil system 23, 24, 25 and the magnetic body 20 in the capsule 18 act as a generator for producing energy.

If a magnetic alternating, rotating or pulse field is generated outside the casing shells 28, 29, the magnetic body 20 in the capsule 18 will align according to the corresponding field and rotates exactly around one axis that is oriented rectangular to the primary field at the location of the body 20, thus causing an optimum localization and generator efficiency. Then, the magnetic dipole 36 that is rigidly mounted on the shaft 34 of the transmission capsule 33 will rotate optimally, if the magnetic field applied outside aligns itself precisely with the rotation axis of said dipole. In this case, the rotation movement is converted forwards or backwards in an optimum manner via the transmission screw 35. Thus, it is possible to generate different fluid pressures on the two sides of the transmission capsule 33. If both ends of the transmission capsule 33 are connected to a hose system, the transmission capsule 33 will act as a pump. Depending on the pumping direction, for example the fluid flows (not shown) in the hose system can be used for direction-changing driving systems. This is achieved by the conversion of the longitudinal motion of the fluid into a rotary motion. Thus, two or more drive wheels or something like can rotate in the transmission capsule 33 towards different directions and consequently the total arrangement can be moved or remotely controlled as desired.

Whereas the rotation axis of the magnetic body 20 in the capsule 18 freely adapts to the applied magnetic field and thus achieves a maximally precise localization and optimum generator performance, the magnetic dipole 36 on the fixed shaft 34 will only behave in the same way if the rotation axis of the exterior magnetic field corresponds to the rotation axis of the dipole. In this case, the rotary field to be localized has reached its highest strength. Apart from the localization of the capsule 18 in space it is also possible to determine an axis orientation of the capsule 18 by aligning the exterior magnetic field three-dimensionally so that the rotation axes of the magnetic body 18 and of the dipole 36 are in alignment and prolong each other and thus generate a maximum rotation field for localization purposes.

The capsule 20 and the transmission capsule 33 can be arranged within the casing 32 so that the inflating bag 39 will expand, if the rotational speeds of the magnetic body 20 are appropriately high and consequently the supporting fluid 19 is heated up. Due to its expansion said bag applies a pressure on the pressure surface 341 at the shaft 34 and thus causes the fixation of the shaft 34 and impedes its rotations. This effect can be used for an extremely precise localization because only one rotation field is generated within the casing 32. Afterwards, when the magnetic body 20 rotates at lower speeds in the capsule 18 and the bearing fluid 19 cools down consequently, the inflating bag 39 lifts off the pressure surface 341 and the shaft 34 with the transmission screw 35 starts to rotate again until the two rotation axes correspond one to the other, as shown above, and the alignment of the axis of the whole casing can be determined.

If the shaft 34 is not provided with a transmission screw, the arrangement with its total contents is used to determine the alignment of the casing shells 28, 29. In this case, the transmission capsule 33 can be provided with or without an additional induction coil 37. The electrical energy generated in one or both capsules 18, 33 can also be used to drive electromotors with flange-mounted motions tractors, not shown in the drawings, via the drive axes 41 and thus for the remotely controlled movement.

The inventive arrangement is suited individually, separately, time-shifted and/or parallel for the following functions or applications to measure parameters for determining and also for controlling and influencing positions and states of the test object, the supporting volume and supporting medium.
localization and indication of the position of the test object,
spatial alignment or indication of the orientation of the test object,
non-contact transmission of energy to or from the test object,
measurement of specific physical and chemical properties or states of the test object, the supporting volume and the supporting medium of the test object,
remotely controlled influence on specific physical and chemical properties or states of the test object, the supporting volume and the supporting medium of the test object, for example to be able to initiate motion sequences, opening mechanisms and/or releasing mechanisms.

All elements presented in the description and the subsequent claims can be decisive for the invention both as single elements and in any combination.

1.-16. (canceled)

17. Apparatus for effecting non-contact defined movement of at least one magnetic body, comprising a body having a magnetic moment, at least one permanent magnet and at least one magnetic field sensor, wherein the body is arranged free to move in at least one dimension in a primary magnetic field of the at least one permanent magnet, the permanent magnet has a secondary magnetic field extending from the body and aligned with the primary magnetic field and the at least one magnetic field sensor registers the secondary magnetic field in any position of the body.

18. Apparatus according to claim 17, further comprising a capsule and wherein the body is a spherical dipole three-dimensionally supported in the capsule.

19. Apparatus according to claim 17, further comprising a liquid in which the body floats.

20. Apparatus according to claim 19, wherein the secondary magnetic field exhibits a lagged phase position relative to the primary magnetic field which reflects the viscosity of the liquid.

21. Apparatus according to claim 17, wherein the permanent magnet is rotationally symmetric about an axis of symmetry, is radially magnetized and is supported for pivoting about said axis.

22. Apparatus according to claim 17, wherein the magnetic field sensor acts in three dimensions.

23. Apparatus according to claim 17, further comprising a compensation system for the magnetic field sensor, wherein the compensation system compensates the primary magnetic field at the magnetic field sensor.

24. Apparatus according to claim 21, wherein the compensation system comprises a magnet fixedly connected to the permanent magnet and supported for pivoting about said axis and at the magnetic field sensor the compensation system generates a field of the same strength as and directed opposite to the primary magnetic field.

25. Apparatus according to claim 17, further comprising at least one other magnetic body and wherein said secondary magnetic field acts as a primary magnetic field for exciting the at least one other magnetic body.

26. Apparatus according to claim 22, wherein the magnetic field sensor is a magnetometer.

27. Apparatus according to claim 18, further comprising a three-dimensionally acting coil system fixed to the capsule.

28. Apparatus according to claim 27, further comprising an evaluation and control unit and wherein movement of the body in the capsule generates currents in the coil system which are transmitted to the evaluation and control unit for determining the spatial location and orientation of the capsule.

29. Apparatus according to claim 27, wherein the coil system and the body comprise a generator for producing energy and the apparatus further comprises means for transmitting the energy for storage or consumption.

30. Apparatus according to claim 29, further comprising means for switching coils of the coil system in series.

31. Apparatus according to claim 29, wherein the body rotates about an axis and the apparatus further comprises a casing and a transmission capsule, the transmission capsule having a shaft which at least approximately aligns with the axis and the capsule and the transmission capsule are fixed on opposite sides of the casing.

32. Apparatus according to claim 28, wherein the evaluation and control unit is electronically connected to the coil system and generates an additional magnetic field via the coil system and the additional magnetic field interferes with the secondary magnetic field of the body as movement of the body occurs.
